(19) United States
(12) Patent Application Publication
(10) Pub. No.: US 2015/0102484 A1
(43) Pub. Date: Apr. 16, 2015

(54) PACKAGE STRUCTURE AND FABRICATION METHOD THEREOF

(71) Applicant: SILICONWARE PRECISION INDUSTRIES CO., LTD, Taichung (TW)

(72) Inventors: Chia-Cheng Chen, Taichung (TW); Ming-Chen Sun, Taichung (TW); Tzu-Chieh Shen, Taichung (TW); Liang-yi Hung, Taichung (TW); Wei-chung Hsiao, Taichung (TW); Yu-cheng Pai, Taichung (TW); Shih-Chao Chiu, Taichung (TW); Don-Son Jiang, Taichung (TW); Yi-Feng Chang, Taichung (TW); Lung-Yuan Wang, Taichung (TW)

(73) Assignee: SILICONWARE PRECISION INDUSTRIES CO., LTD, Taichung (TW)

(21) Appl. No.: 14/136,238

(22) Filed: Dec. 20, 2013

(30) Foreign Application Priority Data
Oct. 16, 2013 (TW) 102137271

(51) Int. Cl. H01L 23/00; H01L 23/31; H01L 23/535

(52) U.S. Cl. CPC H01L 24/67; H01L 24/97; H01L 23/535; H01L 23/3107; H01L 24/14
USPC 257/737; 257/773; 438/107

(57) ABSTRACT

A package structure is disclosed, which includes: a first substrate; a build-up layer formed on and electrically connected to the first substrate and having a cavity; at least an electronic element disposed in the cavity and electrically connected to the first substrate; a stack member disposed on the build-up layer so as to be stacked on the first substrate; and an encapsulant formed between the build-up layer and the stack member. The build-up layer facilitates to achieve a stand-off effect and prevent solder bridging.

### BACKGROUND OF THE INVENTION

1. Field of the Invention

The present invention relates to package structures and fabrication methods thereof, and more particularly, to a package structure and a fabrication method thereof so as to improve the stacking yield.

2. Description of Related Art

Along with the progress of semiconductor packaging technologies, various package types have been developed for semiconductor devices. To improve electrical performances and save spaces, a plurality of packages can be vertically stacked on one another so as to form a package on package (PoP) structure. Such a packaging method allows merging of heterogeneous technologies in a system-in-package (SiP) so as to systematically integrate a plurality of electronic elements having different functions, such as a memory, a CPU (Central Processing Unit), a GPU (Graphics Processing Unit), an image application processor and so on, and therefore is applicable to various thin type electronic products.

Generally, to form a PoP structure, at least two packages are stacked on one another and electrically connected through a plurality of solder balls. However, as the packages tend to have smaller sizes and fine pitches, solder bridging easily occurs between the solder balls of the PoP structure, thus adversely affecting the product yield.

Accordingly, copper pillars are formed to achieve a stand-off effect so as to prevent solder bridging. FIGS. 1A and 1B are schematic cross-sectional views showing a method for fabricating a PoP structure 1 according to the prior art.

Referring to FIG. 1A, a first substrate 11 having a first surface 11a with a plurality of copper pillars 13 and a second surface 11b opposite to the first surface 11a is provided.

Referring to FIG. 1B, an electronic element 15 is disposed on the first surface 11a and electrically connected to the first substrate 11 in a flip-chip manner. Then, a second substrate 12 is stacked on the first substrate 11 through the copper pillars 13. In particular, the second substrate 12 is bonded to the copper pillars 13 of the first substrate 11 through a plurality of conductive elements 17. Each of the conductive elements 17 consists of a metal pillar 170 and a solder material 171 formed on the metal pillar 170. Subsequently, an encapsulant 16 is formed between the first surface 11a of the first substrate 11 and the second substrate 12.

However, since the copper pillars 13 are formed by electroplating, the size of the copper pillars 13 is difficult to control and liable to cause uneven heights of the copper pillars 13. Consequently, a positional deviation easily occurs to the joints between the conductive elements 17 and the copper pillars 13 so as to result in a poor bonding therebetween, thus adversely affecting the electrical performance and reducing the product yield.

Therefore, there is a need to provide a package structure and a fabrication method thereof so as to overcome the above-described drawbacks.

### SUMMARY OF THE INVENTION

In view of the above-described drawbacks, the present invention provides a package structure, which comprises: a first substrate; a build-up layer formed on and electrically connected to the first substrate and having a cavity; at least an electronic element disposed in the cavity and electrically connected to the first substrate; a stack member disposed on the build-up layer so as to be stacked on the first substrate; and an encapsulant formed between the build-up layer and the stack member.

The present invention further provides a method for fabricating a package structure, which comprises the steps of: providing a first substrate having a build-up layer formed thereon, wherein the build-up layer has a cavity; disposing at least an electronic element in the cavity and electrically connecting the electronic element to the first substrate; and disposing a stack member on the build-up layer so as to stack the stack member on the first substrate.

The method can further comprise forming an encapsulant between the build-up layer and the stack member.

In the above-described method, fabricating the first substrate can comprise: providing the first substrate; and forming the build-up layer on the first substrate and forming the cavity in the build-up layer, wherein the build-up layer is electrically connected to the first substrate.

In the above-described method, forming the build-up layer can comprise: forming at least a dielectric layer on the first substrate and forming the cavity and a plurality of openings in the dielectric layer; and forming in the openings of the dielectric layer a plurality of conductive members electrically connected to the first substrate.

The dielectric layer can be made of prepreg. In an embodiment, the dielectric layer is laminated on the first substrate first and then the cavity is formed in the dielectric layer. In another embodiment, the cavity is formed in the dielectric layer first and then the dielectric layer having the cavity is laminated on the first substrate.

The cavity and the openings of the dielectric layer can be formed by laser drilling. The conductive members can be made of metal and can be of a pillar shape or a groove shape.

The stack member can be bonded to the conductive members through a plurality of conductive elements.

Further, a circuit layer can be formed on the dielectric layer and electrically connected to the conductive members.

Further, an insulating layer can be formed on the dielectric layer and expose the conductive members so as for an encapsulant to be formed between the insulating layer and the stack member.

In the above-described package structure and method, the first substrate can be a circuit board.

In the above-described package structure and method, a surface of the first substrate can be partially exposed from the cavity so as for the electronic element to be disposed thereon.

In the above-described package structure and method, the electronic element can be an active component or a passive component.

In the above-described package structure and method, the stack member can be bonded to the build-up layer through a plurality of conductive elements.

In the above-described package structure and method, the stack member can be a second substrate or a package. The second substrate can be a circuit board.

In the above-described package structure and method, the stack member can be narrower than the first substrate such that the stack member is encapsulated by the encapsulant.

In the above-described package structure and method, the encapsulant can be further formed between the first substrate and the stack member.

Therefore, by forming the build-up layer on the first substrate so as to stack the stack member on the build-up layer, the present invention achieves a stand-off effect and prevents solder bridging.

Further, the size of the conductive members can be controlled through the openings of the dielectric layer so as to cause the conductive members to have a uniform height. Therefore, the present invention overcomes the conventional drawback of joint deviation and ensures a reliable bonding between the conductive elements and the conductive members, thereby improving the product yield.

### BRIEF DESCRIPTION OF DRAWINGS

FIGS. 1A and 1B are schematic cross-sectional views showing a method for fabricating a package on package (PoP) structure according to the prior art;

FIGS. 2A to 2F are schematic cross-sectional views showing a method for fabricating a package structure according to the present invention, wherein FIG. 2C′ shows another embodiment of FIG. 2C; and

FIGS. 3 and 4 are schematic cross-sectional views showing other embodiments of the package structure of the present invention.

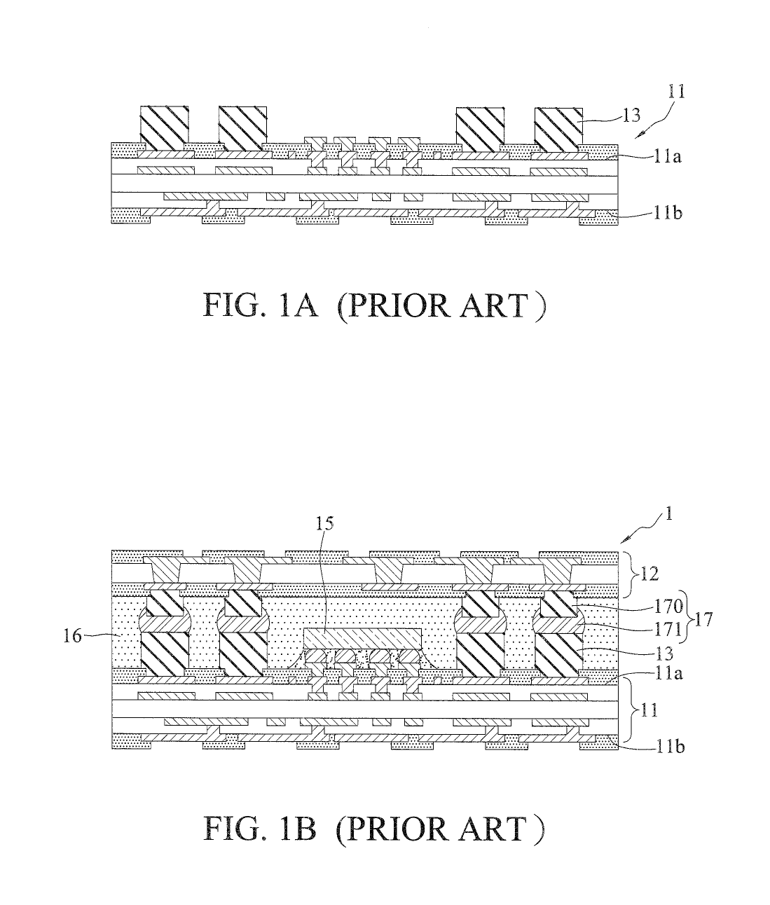

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “lower”, “first”, “second”, “on”, “a” etc. are merely for illustrative purposes and should not be construed to limit the scope of the present invention.

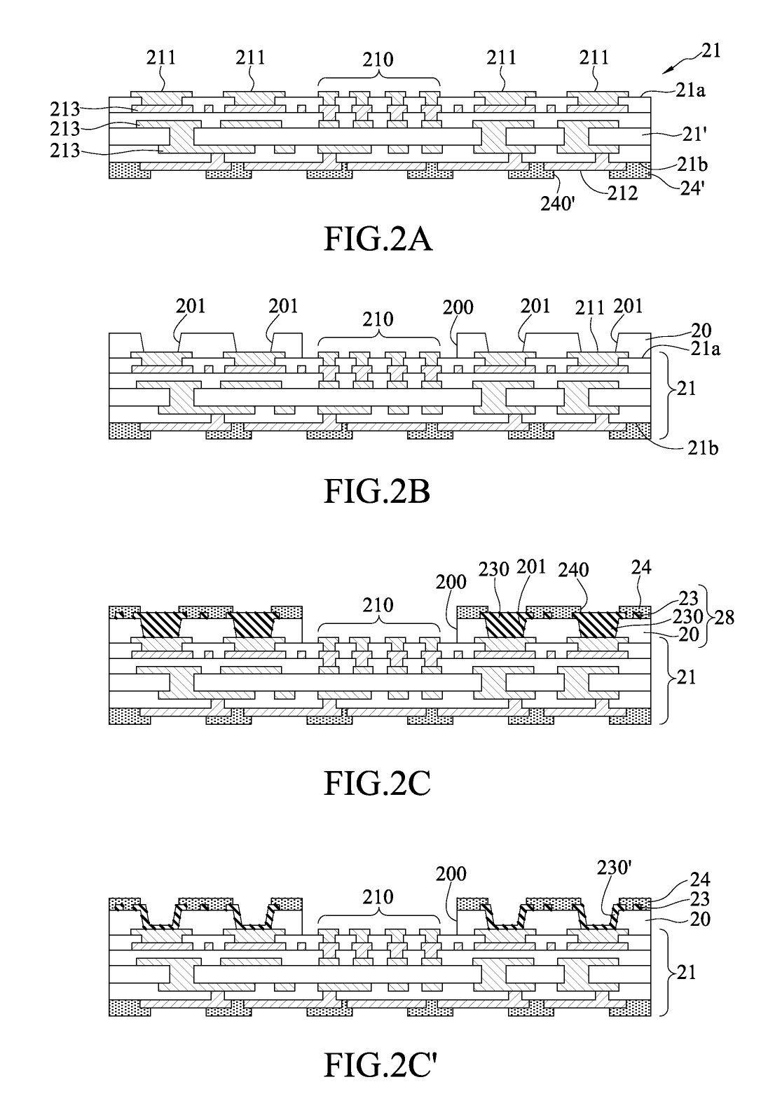

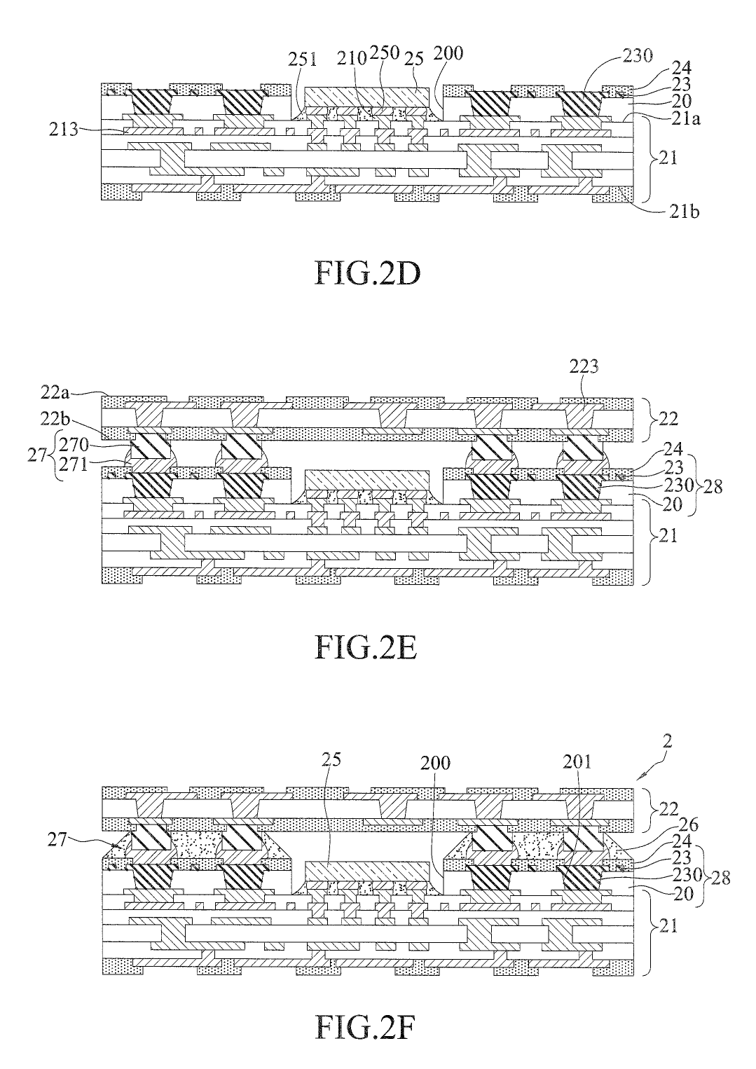

FIGS. 2A to 2F are schematic cross-sectional views showing a method for fabricating a package structure 2 according to the present invention.

Referring to FIG. 2A, a first substrate 21 having a first surface 21a and a second surface 21b opposite to the first surface 21a is provided.

In the present embodiment, the first substrate 21 is a circuit board having a core layer 21′ and a plurality of circuits 213 formed on upper and lower sides of the core layer 21′. Further, the first surface 21a of the first substrate 21 has a plurality of first bonding pads 210 and a plurality of second bonding pads 211, and the second surface 21b of the first substrate 21 has a plurality of third bonding pads 212.

The number of the circuits 213 on the upper side of the core layer 21′ can be the same as or different from the number of the circuits 213 on the lower side of the core layer 21′.

Further, an insulating layer 24′ such as a solder mask layer can be formed on the second surface 21b of the first substrate 21 and have a plurality of openings 240′ for exposing the third bonding pads 212.

Referring to FIG. 2B, a dielectric layer 20 is formed on the first surface 21a of the first substrate 21. The dielectric layer 20 has a cavity 200 for exposing the first bonding pads 210 and a portion of the first surface 21a around peripheries of the first bonding pads 210, and a plurality of openings 201 for exposing the second bonding pads 211.

In the present embodiment, the dielectric layer 20 is laminated on the first surface 21a of the first substrate 21 first and then the cavity 200 and the openings 201 are formed in the dielectric layer 20 by laser drilling. In other embodiments, the cavity 200 and the openings 201 are formed in the dielectric layer 20 first and then the dielectric layer 20 having the cavity 200 and the openings 201 is laminated on the first surface 21a of the first substrate 21.

The dielectric layer 20 can be made of prepreg (PP).

Referring to FIG. 2C, a circuit layer 23 is formed on the dielectric layer 20 and a plurality of conductive members 230 are formed in the openings 201 of the dielectric layer 20. As such, the dielectric layer 20, the circuit layer 23 and the conductive members 230 together form a build-up layer 28. The conductive members 230 electrically connect the circuit layer 23 to the second bonding pads 211 and the circuits 213 of the first substrate 21.

In the present embodiment, an insulating layer 24, such as a solder mask layer, is formed on the dielectric layer 20 and the circuit layer 23, and a plurality of openings 240 are formed in the insulating layer 24 for exposing the conductive members 230.

Further, the conductive members 230 are made of a metal material, such as copper, and the conductive members 230 are of a pillar shape.

In another embodiment, referring to FIG. 2C′, the conductive members 230′ can be of a groove shape.

Referring to FIG. 2D, an electronic element 25 is disposed on the first bonding pads 210 in the cavity 200 through a plurality of solder bumps 250 and an underfill 251 is formed between the first substrate 21 and the electronic element 25 for encapsulating the solder bumps 250. As such, the electronic element 25 is disposed on the first surface 21a of the first substrate 21 to form a package, and the electronic element 25 is electrically connected to the circuits 213 and the first bonding pads 210 of the first substrate 21 in a flip-chip manner.

In the present embodiment, the electronic element 25 is an active component, such as a chip, and/or a passive component, such as a resistor, a capacitor or an inductor.

In other embodiments, the electronic element 25 can be electrically connected to the first substrate 21 through wire bonding.

Referring to FIG. 2E, a stack member 22 is disposed on the conductive members 230 so as to be stacked on the build-up layer 28 and cover the electronic element 25.

In the present embodiment, the stack member 22 is a second substrate, such as a circuit board. The stack member 22 is bonded to the conductive members 230 through a plurality of conductive elements 27. For example, a plurality of conductive elements 27 made of such as a solder material are formed on a lower surface 22b of the stack member 22 and electrically connected to the conductive members 230 so as to stack the stack member 22 on the build-up layer 28. Alternatively, a plurality of conductive elements 27 each consisting of a metal pillar 270 (such as a copper pillar) and a solder material 271 formed on the metal pillar 270 can be formed between the conductive members 230 and the stack member 22 so as to stack the stack member 22 on the build-up layer 28.

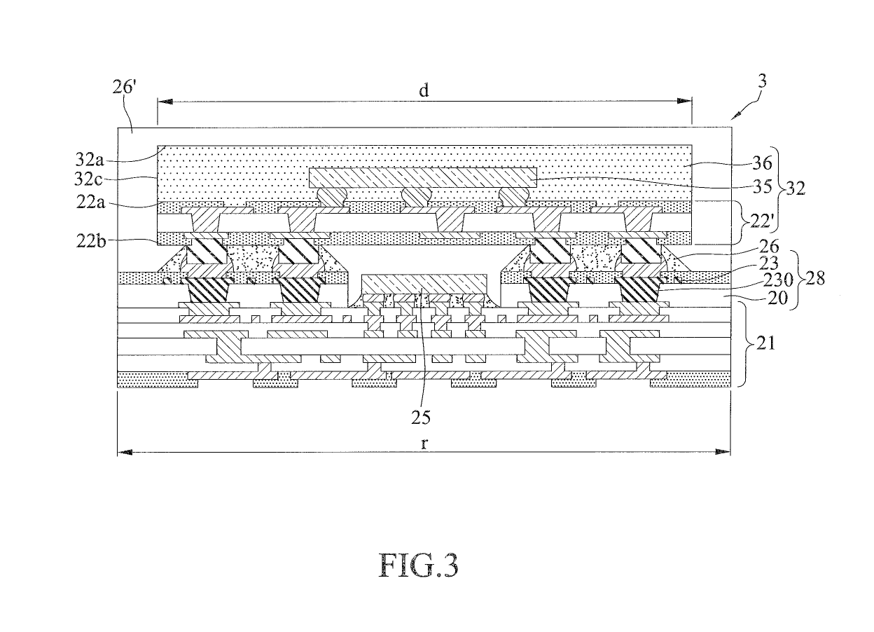

Further, referring to FIG. 3, the stack member 32 can be a package, which has: a substrate 22′, an electronic element 35 disposed on an upper surface 22a of the substrate 22′, and an encapsulant 36 formed on the upper surface 22a of the substrate 22′ for encapsulating the electronic element 35. The electronic element 35 is electrically connected to the substrate 22′ in a flip-chip manner or through wire bonding.

Referring to FIG. 2F, an encapsulant 26 is formed between the first surface 21a of the first substrate 21 and the stack member 22.

In the present embodiment, the encapsulant 26 is formed between the dielectric layer 20 (or the insulating layer 24) and the stack member 22, but is not formed in the cavity 200. Therefore, the conductive elements 27 are encapsulated by the encapsulant 26, but the electronic element 25 is not encapsulated by the encapsulant 26. In other embodiments, the encapsulant 26 can be filled between the first surface 21a of the first substrate 21 and the stack member 22 so as to encapsulate the conductive elements 27 and the electronic element 25.

In another embodiment, referring to FIG. 3, the width d of the stack member 32 is less than the width r of the first substrate 21 so as for the encapsulant 26′ to encapsulate both side and upper surfaces 32c, 32a of the stack member 32.

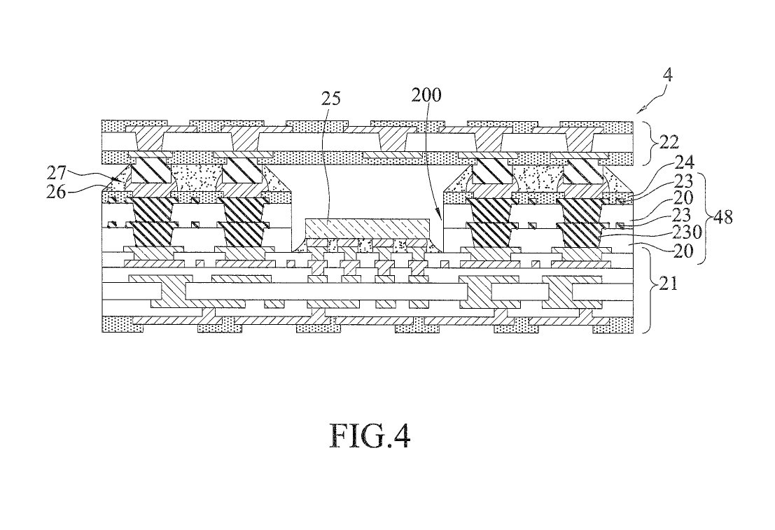

In another embodiment, referring to FIG. 4, the build-up layer 48 of the package structure 4 has a plurality of dielectric layers 20 and a plurality of circuit layers 23.

Therefore, the present invention forms on the first substrate 21 the build-up layer 28 having the conductive members 230 embedded in the dielectric layer 20 and stacks the stack member 22, 32 on the build-up layer 28, thus achieving a stand-off effect on the conductive members 230 and preventing solder bridging from occurring therebetween.

Further, the size of the conductive members 230 can be controlled through the openings 201 of the dielectric layer 20 so as to cause the conductive members 230 to have a uniform height. Therefore, the present invention overcomes the conventional drawback of joint deviation and prevents poor contacts or short circuits from occurring between the conductive elements 27 and the conductive members 230, thereby improving the product yield.

The present invention further provides a package structure 2, 3, 4, which has: a first substrate 21; a build-up layer 28, 48 formed on and electrically connected to the first substrate 21; an electronic element 25 disposed on and electrically connected to the first substrate 21; a stack member 22, 32 stacked on the build-up layer 28, 48 so as to be stacked on the first substrate 21; and an encapsulant 26, 26′ formed between the build-up layer 28, 48 (or the insulating layer 24) and the stack member 22, 32.

The first substrate 21 is a circuit board, which has opposite first and second surfaces 21a, 21b.

The build-up layer 28, 48 has a cavity 200 exposing a portion of the first surface 21a of the first substrate 21.

In the present embodiment, the build-up layer 28, 48 has: at least a dielectric layer 20 formed on the first substrate 21, a circuit layer 23 formed on the dielectric layer 20, and a plurality of conductive members 230 formed in and exposed from the dielectric layer 20.

In particular, the cavity 200 penetrates the dielectric layer 20. The dielectric layer 20 further has a plurality of openings 201. The dielectric layer 20 can be made of prepreg. The conductive members 230, 230′ are formed in the openings 201 of the dielectric layer 20 for electrically connecting the circuit layer 23 and the first substrate 21. The conductive members 230, 230′ are made of metal and of a pillar shape or a groove shape. The package structure 2, 3, 4 can further have an insulating layer 24 formed on the build-up layer 28, 48 and exposing the conductive members 230, 230′.

The electronic element 25 is an active component or a passive component. The electronic element 25 is disposed on the first surface 21a of the first substrate 21 in the cavity 200.

The stack member 22, 32 is disposed on the build-up layer 28, 48. In particular, the stack member 22, 32 is bonded to the conductive members 230, 230′ through a plurality of conductive elements 27 so as to be stacked on the first substrate 21.

In an embodiment, the encapsulant 26′ is further formed between the first substrate 21 and the stack member 32.

In an embodiment, the stack member 22 is a second substrate such as a circuit board. In another embodiment, the stack member 32 is a package.

In an embodiment, the width d of the stack member 32 is less than the width r of the first substrate 21 so as for the encapsulant 26′ to encapsulate the stack member 32.

Therefore, by forming the dielectric layer on the first substrate and embedding the conductive members in the dielectric layer and further stacking the stack member on the build-up layer, the present invention achieves a stand-off effect and prevents solder bridging.

Further, the size of the conductive members can be controlled through the openings of the dielectric layer so as to cause the conductive members to have a uniform height. Therefore, the present invention overcomes the conventional drawback of joint deviation and ensures a reliable bonding between the conductive elements and the conductive members, thereby improving the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

1. A package structure, comprising:
a first substrate;
a build-up layer formed on and electrically connected to the first substrate and having a cavity, wherein the build-up layer comprises:
at least a dielectric layer formed on the first substrate, wherein the cavity penetrates the dielectric layer; and
at least a conductive member formed in and exposed from the dielectric layer and electrically connected to the first substrate, wherein the conductive member is of a pillar shape or a groove shape;
at least an electronic element disposed in the cavity and electrically connected to the first substrate;
a stack member disposed on the build-up layer so as to be stacked on the first substrate, wherein the stack member is bonded to the conductive member; and
an encapsulant formed between the build-up layer and the stack member.

2. The package structure of claim 1, wherein the first substrate is a circuit board.

3. The package structure of claim 1, wherein the first substrate has a surface partially exposed from the cavity so as for the electronic element to be disposed thereon.

4. (canceled)

5. The package structure of claim 1, wherein the dielectric layer is made of prepreg.

6. The package structure of claim 1, wherein the at least conductive member is made of metal.

7. (canceled)

8. The package structure of claim 1, further comprising a plurality of conductive elements, wherein the stack member is bonded to the at least conductive member through the conductive elements.

9. The package structure of claim 1, further comprising a circuit layer formed on the dielectric layer and electrically connected to the at least a conductive member.

10. The package structure of claim 1, further comprising an insulating layer formed on the build-up layer and exposing the at least a conductive member.

11. The package structure of claim 10, wherein the encapsulant is formed between the insulating layer and the stack member.

12. The package structure of claim 1, wherein the electronic element is an active component or a passive component.

13. The package structure of claim 1, further comprising a plurality of conductive elements, wherein the stack member is bonded to the build-up layer through the conductive elements.

14. The package structure of claim 1, wherein the stack member is a second substrate or a package.

15. The package structure of claim 14, wherein the second substrate is a circuit board.

16. The package structure of claim 1, wherein the stack member is narrower than the first substrate.

17. The package structure of claim 16, wherein the stack member is encapsulated by the encapsulant.

18. The package structure of claim 1, wherein the encapsulant is further formed between the first substrate and the stack member.

19. A method for fabricating a package structure, comprising the steps of:
providing a first substrate having a build-up layer formed thereon, wherein forming the build-up layer comprises:
forming at least a dielectric layer on the first substrate and forming a cavity and a plurality of openings in the dielectric layer; and
forming a plurality of conductive members electrically connected to the first substrate in the openings of the dielectric layer, wherein the conductive members are of a pillar shape or a groove sham;
disposing at least an electronic element in the cavity and electrically connecting the electronic element to the first substrate; and
disposing a stack member on the build-up layer so as to stack the stack member on the first substrate, wherein the stack member is bonded to the conductive members.

20. The method of claim 19, wherein fabricating the first substrate comprises:
providing the first substrate; and
forming the build-up layer on the first substrate and forming the cavity in the build-up layer, wherein the build-up layer is electrically connected to the first substrate.

21. The method of claim 19, wherein the first substrate is a circuit board.

22. The method of claim 19, wherein a surface of the first substrate is partially exposed from the cavity so as for the electronic element to be disposed thereon.

23. (canceled)

24. The method of claim 19, wherein the dielectric layer is laminated on the first substrate first and then the cavity is formed in the dielectric layer.

25. The method of claim 19, wherein the cavity is formed in the dielectric layer first and then the dielectric layer having the cavity is laminated on the first substrate.

26. The method of claim 19, wherein the dielectric layer is made of prepreg.

27. The method of claim 19, wherein the cavity and the openings are formed by laser drilling.

28. The method of claim 19, wherein the conductive members are made of metal.

29. (canceled)

30. The method of claim 19, wherein the stack member is bonded to the conductive members through a plurality of conductive elements.

31. The method of claim 19, further comprising forming on the dielectric layer a circuit layer that is electrically connected to the conductive members.

32. The method of claim 19, further comprising forming an insulating layer on the build-up layer and exposing the conductive members from the insulating layer.

33. The method of claim 32, further comprising forming an encapsulant between the insulating layer and the stack member.

34. The method of claim 19, wherein the electronic element is an active component or a passive component.

35. The method of claim 19, wherein the stack member is bonded to the build-up layer through a plurality of conductive elements.

36. The method of claim 19, wherein the stack member is a second substrate or a package.

37. The method of claim 36, wherein the second substrate is a circuit board.

38. The method of claim 19, wherein the stack member is narrower than the first substrate.

39. The method of claim 38, further comprising forming an encapsulant between the build-up layer and the stack member, wherein the stack member is encapsulated by the encapsulant.

40. The method of claim 19, further comprising forming an encapsulant between the build-up layer and the stack member.

41. The method of claim 40, wherein the encapsulant is further formed between the first substrate and the stack member.
